(19) United States
(12) Patent Application Publication
(10) Pub. No.: US 2025/0351344 A1
(43) Pub. Date: Nov. 13, 2025

(54) SEMICONDUCTOR DEVICE AND METHOD OF FORMING THE SAME

(71) Applicant: Winbond Electronics Corp., Taichung City (TW)

(72) Inventors: Wei-Zhi Fang, Tainan City (TW); Shu-Ming Li, Kaohsiung City (TW); Tzu-Ming Ou Yang, Taichung City (TW)

(73) Assignee: Winbond Electronics Corp., Taichung City (TW)

(21) Appl. No.: 18/818,628

(22) Filed: Aug. 29, 2024

(30) Foreign Application Priority Data
May 8, 2024 (TW) 113117044

(51) Int. Cl. H10B 41/42; H10B 41/30; H10B 43/30; H10B 43/40

(52) U.S. Cl. CPC H10B 41/42; H10B 41/30; H10B 43/30; H10B 43/40

(57) ABSTRACT

A semiconductor device of this invention is provided, including a substrate, a plurality of gate structures, a spacer, and a plurality of contacts. The plurality of gate structures are disposed on the substrate. Each gate structure includes a tunneling dielectric layer and a word line stack disposed on the tunneling dielectric layer. The spacer is disposed on the tunneling dielectric layer and covers a sidewall of the word line stack. The plurality of contacts are respectively disposed between the plurality of gate structures, wherein the tunneling dielectric layer includes a protrusion protruding outward from a sidewall of the spacer to a corresponding contact.

### CROSS-REFERENCE TO RELATED APPLICATION

This application claims the priority benefit of Taiwan application serial no. 113117044, filed on May 8, 2024. The entirety of the above-mentioned patent application is hereby incorporated by reference herein and made a part of this specification.

### BACKGROUND

### Technical Field

The disclosure relates to a semiconductor device and a method of forming the same.

### Description of Related Art

As the size of semiconductor devices is increasingly smaller, devices with more functions are integrated on one single chip. In this case, the line width in the semiconductor devices is also gradually reduced to make electronic products light, thin, and compact according to requirements. However, semiconductor process technology will also face many challenges. For example, the shoulder of the word line stacks may be damaged by subsequent etching processes. In this case, word line leakage issues may easily occur.

### SUMMARY

The disclosure provides a semiconductor device, including: a substrate, a plurality of gate structures, a spacer, and a plurality of contacts. The plurality of gate structures are disposed on the substrate. Each gate structure includes a tunneling dielectric layer and a word line stack disposed on the tunneling dielectric layer. The spacer is disposed on the tunneling dielectric layer and covers a sidewall of the word line stack. The plurality of contacts are respectively disposed between the plurality of gate structures, wherein the tunneling dielectric layer includes a protrusion protruding outward from a sidewall of the spacer to a corresponding contact.

The disclosure provides a method of forming a semiconductor device, including: forming a dielectric layer on a substrate; forming a plurality of word line stacks on the dielectric layer and a spacer covering a sidewall of the plurality of word line stacks; forming a sacrificial material between the plurality of word line stacks; removing the sacrificial material to form a plurality of first openings, wherein the plurality of first openings expose a surface of the dielectric layer; forming a protective layer to cover a sidewall of the spacer and a bottom surface of the plurality of first openings; with the protective layer in place, performing a first etching process to remove the protective layer and the dielectric layer at a bottom of the plurality of first openings, thereby forming a plurality of second openings in the dielectric layer to expose a bottom surface of the substrate; and respectively forming a plurality of contacts in the plurality of first openings and the plurality of second openings.

Based on the above, in the embodiment of the present invention, after removing the sacrificial material between the plurality of word line stacks, a protective layer is formed to cover the surface of the plurality of word line stacks to prevent the subsequent etching process from damaging the shoulders and sidewalls of the plurality of word line stacks. In this case, the embodiment of the present invention can effectively solve the conventional word line leakage issue, thereby improving the yield and reliability of the semiconductor device.

### BRIEF DESCRIPTION OF THE DRAWINGS

FIG. 1A to FIG. 1E and FIG. 2A to FIG. 2B are schematic cross-sectional views of a manufacturing process of a semiconductor device according to various embodiments of the disclosure.

### DESCRIPTION OF THE EMBODIMENTS

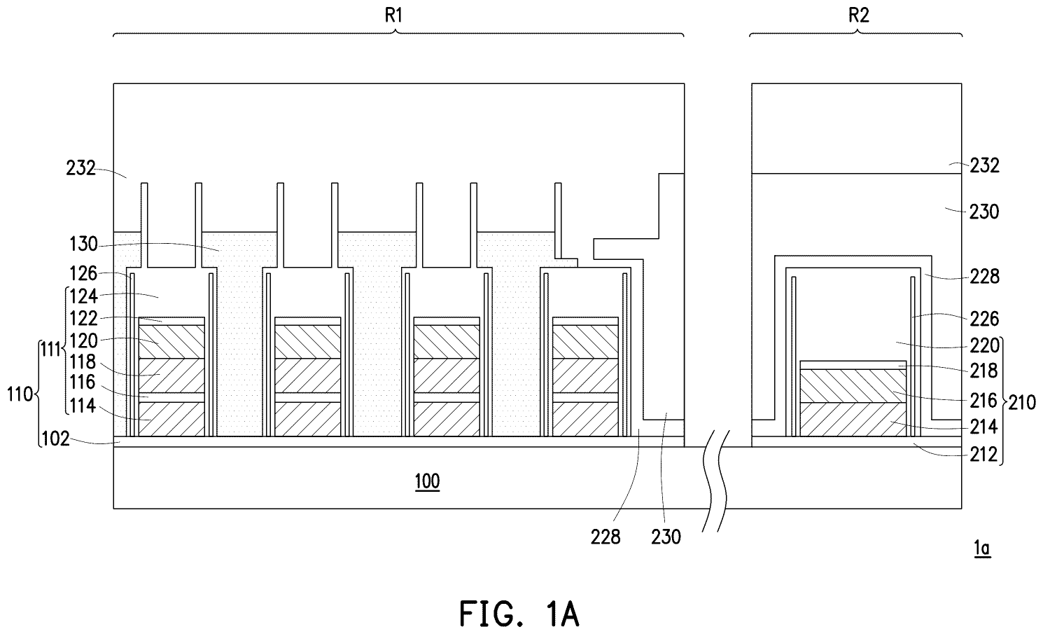

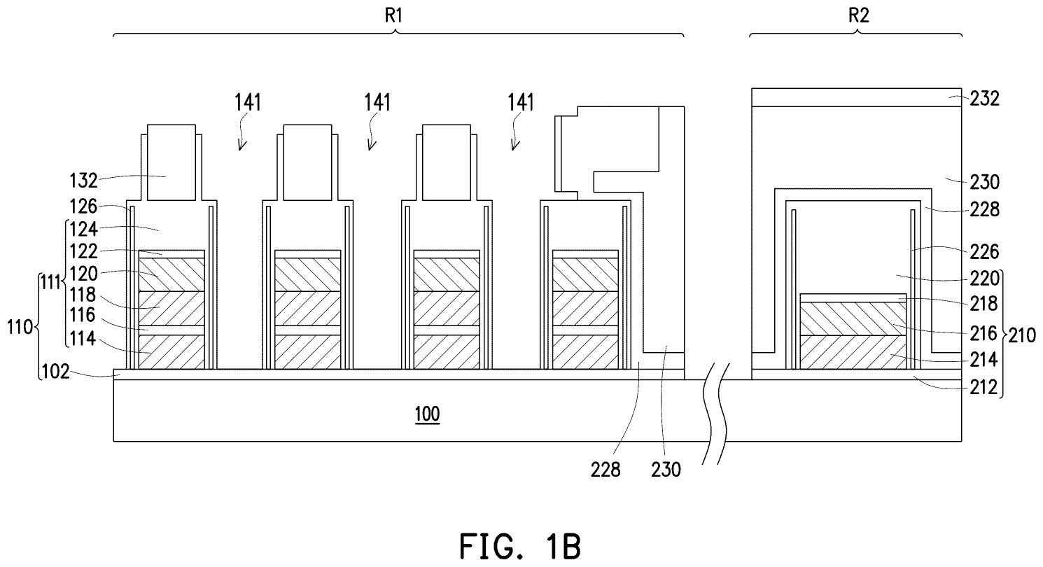

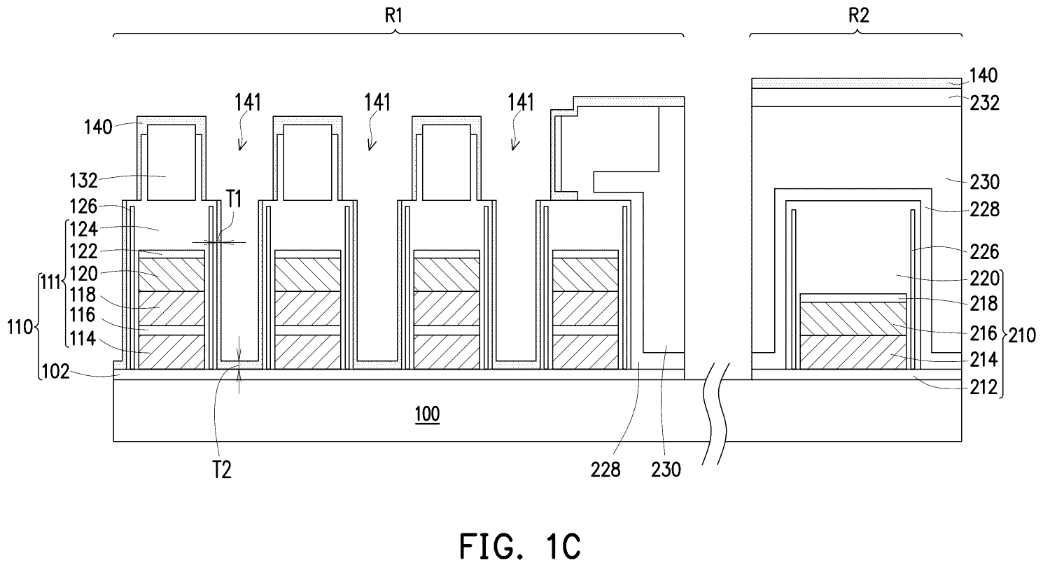

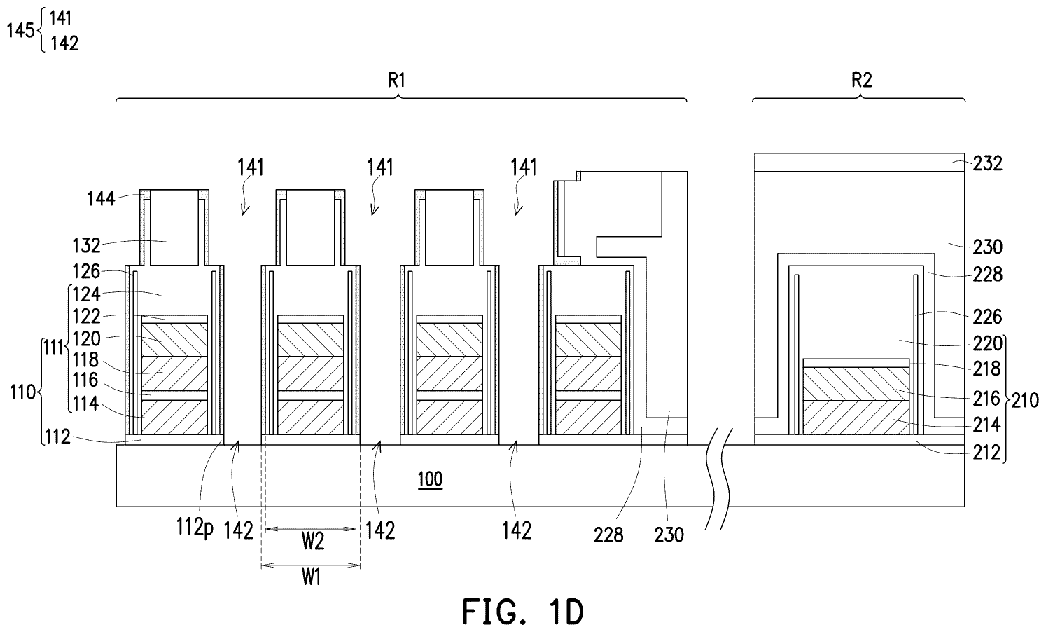

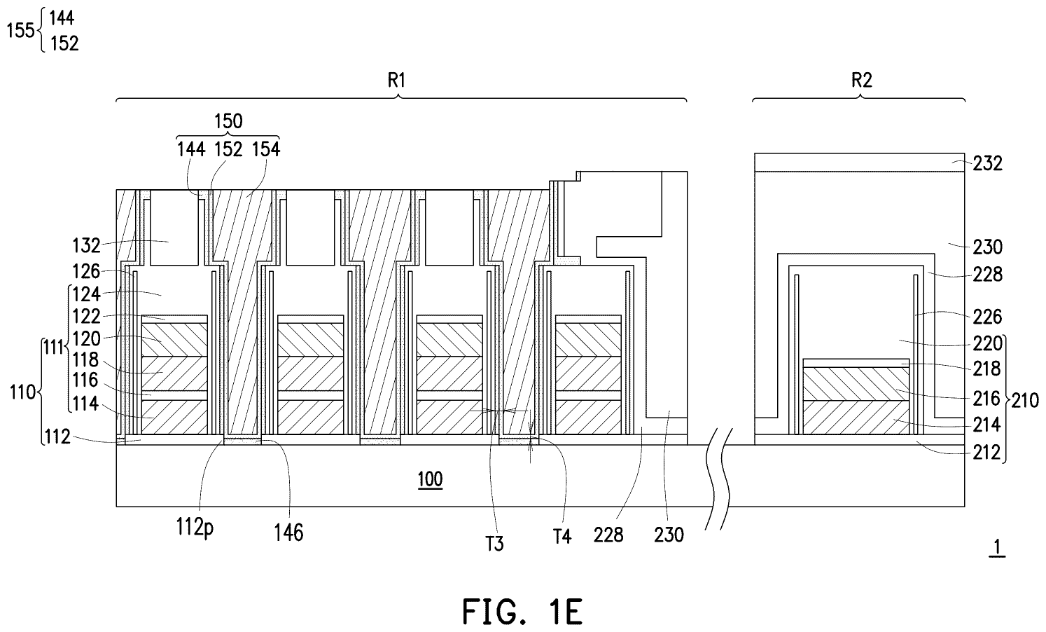

FIG. 1A to FIG. 1E are schematic cross-sectional views of a manufacturing process of a semiconductor device according to a first embodiment of the disclosure.

Referring to FIG. 1A, the present embodiment provides a method of manufacturing a semiconductor device 1 (as shown in FIG. 1E) including following steps. First, provided is an initial structure la which includes a substrate 100, a dielectric layer 102, a plurality of word line stacks 111, and at least one second gate structure 210. The substrate 100 may include a first region R1 and a second region R2. The first region R1 may be a memory cell region, and the second region R2 may be a peripheral region. The substrate 100 may be a semiconductor substrate, a semiconductor compound substrate, or a semiconductor over insulator (SOI) substrate. The substrate 100 may be a silicon substrate.

The dielectric layer 102 may be disposed on the substrate 100 in the first region R1. A material of the dielectric layer 102 may be, for example, silicon oxide, may be formed by chemical vapor deposition (CVD), thermal oxidation, or the like. The dielectric layer 102 may be subsequently patterned to form the tunneling dielectric layer 112 (as shown in FIG. 1D).

A plurality of word line stacks 111 may be disposed on the dielectric layer 102 to form a plurality of first gate structures 110. The first gate structure 110 may be a flash memory structure. Specifically, each word line stack 111 may include a first conductive layer 114, an inter-gate dielectric layer 116, a second conductive layer 118, a third conductive layer 120, a first capping layer 122 and a second capping layer 124. A material of the first conductive layer 114 may be, for example, doped polycrystalline silicon, non-doped polycrystalline silicon, or a combination thereof, and may be formed by chemical vapor deposition. The inter-gate dielectric layer 116 may be, for example, a composite layer composed of oxide/nitride/oxide (ONO), but the invention is not limited thereto. The composite layer may be three layers or five layers. layer or more layers; the inter-gate dielectric layer 116 may be formed by, for example, chemical vapor deposition. A material of the second conductive layer 118 may be, for example, doped polycrystalline silicon, non-doped polycrystalline silicon, or a combination thereof, and may be formed by chemical vapor deposition. A material of the third conductive layer 120 may include a metal material, such as W, Cu, and AlCu, and may be formed by physical vapor deposition. A material of the first capping layer 122 and the second capping layer 124 may include a dielectric material, such as silicon nitride, silicon oxynitride, or combinations thereof, and may be formed by chemical vapor deposition. The first capping layer 122 and the second capping layer 124 may include different dielectric materials. For example, the first capping layer 122 is a silicon nitride layer, and the second capping layer 124 is a silicon oxide layer.

At least one second gate structure 210 may be disposed on the substrate 100 in the second region R2. Specifically, the second gate structure 210 may include a gate dielectric layer 212, a fourth conductive layer 214, a fifth conductive layer 216, a third capping layer 218, and a fourth capping layer 220 in order from bottom to top. A material of the gate dielectric layer 212 may be, for example, silicon oxide, and may be formed by chemical vapor deposition, thermal oxidation, or the like. A material of the fourth conductive layer 214 may include a conductive material, such as doped polycrystalline silicon, non-doped polycrystalline silicon, or a combination thereof, and may be formed by chemical vapor deposition. A material of the fifth conductive layer 216 may include a metal material, such as W, Cu, AlCu, or the like, and may be formed by physical vapor deposition. A material of the third capping layer 218 and the fourth capping layer 220 may include a dielectric material, such as silicon nitride, silicon oxynitride, or a combination thereof, and may be formed by chemical vapor deposition. The third capping layer 218 and the fourth capping layer 220 may include different dielectric materials. For example, the third capping layer 218 is a silicon nitride layer, and the fourth capping layer 220 is a silicon oxide layer.

The first gate structure 110 and the second gate structure 210 may have different sizes, such as different heights and/or different widths. In addition, a thickness of the gate dielectric layer 212 of the second gate structure 210 may be different from a thickness of the dielectric layer 102 of the first gate structure 110. Further, although FIG. 1A only illustrates a single second gate structure 210, the present invention is not limited thereto. The number of the second gate structure 210 may be adjusted according to needs.

As shown in FIG. 1A, the initial structure la further includes spacers 126, 226, a sacrificial material 130, a stop layer 228, an interlayer dielectric (ILD) layer 230, and a planarization layer 232. Specifically, the spacer 126 may be formed on the dielectric layer 102 in the first region R1 and cover sidewalls of the plurality of word line stacks 111. On the other hand, the spacer 226 may be formed on the second region R2 and cover a sidewall of the second gate structure 210. The spacers 126 and 226 may include a single-layered structure, a bi-layered structure, or a multi-layered structure. For example, the spacers 126 and 226 each include a silicon oxide layer, a silicon nitride layer, and a silicon oxide layer.

The sacrificial material 130 may be formed between the plurality of word line stacks 111. In detail, the sacrificial material 130 may be filled into spaces between the plurality of word line stacks 111 to form a T-shape in the cross-section of FIG. 1A. A material of the sacrificial material 130 may include a conductive material, such as doped polycrystalline silicon, non-doped polycrystalline silicon, or a combination thereof, and may be formed by chemical vapor deposition.

The stop layer 228 may conformally cover the second gate structure 210 and the sidewalls of the word line stack 111 adjacent to the second region R2. A material of the stop layer 228 may include a dielectric material, such as silicon nitride, silicon oxynitride and other nitrogen-containing dielectric materials, and may be formed by chemical vapor deposition.

The interlayer dielectric layer 230 may be formed on the stop layer 228 in the second region R2 and the stop layer 228 adjacent to the sidewall of the word line stack 111 adjacent to the second region R2. A material of the interlayer dielectric layer 230 includes a dielectric material such as silicon oxide and low-k dielectric material. Here, the so-called low-k dielectric material means that a dielectric material having the dielectric constant less than or equal to 4.

The planarization layer 232 may be formed on the interlayer dielectric layer 230 and the sacrificial material 130, and extends to cover a portion of the top surface of the word line stacks 111. A material of the planarization layer 232 may be, for example, silicon nitride, and may be formed by chemical vapor deposition.

Referring to FIG. 1B, the sacrificial material 130 is removed to form a plurality of first openings 141. Specifically, the planarization layer 232 is first removed to expose the sacrificial material 130, and then the sacrificial material 130 is removed to expose the surface of the dielectric layer 102. That is, the first openings 141 may expose the surface of the dielectric layer 102 and the surface of the spacer 126 overlying the sidewalls of the word line stacks 111. In this case, as shown in FIG. 1B, the remaining planarization layer 132 on the first region R1 is formed on a portion of the top surfaces of the word line stacks 111 to separate the first openings 141 from each other.

Referring to FIG. 1C, a protective material 140 is formed to cover the sidewall of the spacer 126 and the bottom surfaces of the first openings 141. Specifically, the protective material 140 may cover the surface of the first openings 141, the surface of the planarization layer 132, and the surface of the planarization layer 232. The protective material 140 may include a barrier metal (e.g., Ti, TiN, Ta, TaN, or the like), and may be formed by a radiofrequency magnetron sputtering (RF) deposition process. It should be noted that the protective material 140 formed by the RF deposition process has the poor step coverage. That is to say, a thickness T1 of the protective material 140 covering the sidewall of the first opening 141 (or the spacer 126) is less than a thickness T2 of the protective material 140 covering the bottom surface of the first opening 141. The step coverage of the protective material 140 is between 20% and 50%, where the step coverage is defined as a ratio of thickness T1 to thickness T2 (T1/T2).

Referring to FIG. 1C and FIG. 1D, with the protective material 140 in place, a first etching process is performed to remove the protective material 140 and the dielectric layer 102 at bottoms of the first openings 141, thereby forming a plurality of second openings 142 in the dielectric layer 112 exposing the bottom surface of the substrate 100. The first etching process may be a dry etching process, such as a reactive ion etching (RIE) process. Specifically, the first etching process includes a first etching step and a second etching step. The first etching step is used to remove a portion of the protective material 140, while the second etching step is used to remove a portion of the dielectric layer 102. Therefore, the first etching step and the second etching step may use different etching gases. For example, when the protective material 140 is TiN and the dielectric layer 102 is silicon oxide, the first etching step includes a chlorine-based (Cl-based) etching gas, while the second etching step includes a fluorine-based (F-based) etching gas. Also, in addition to the protective material 140 at the bottoms of the first openings 141, the first etching process also removes the protective material 140 on the top surface of the planarization layer 132 and the top surface of the spacer 126 (or the shoulders of the word line stacks 111). It should be noted that since the above-mentioned second etching step has high etching selectivity with respect to the dielectric layer 112, the protective material 140 can protect the shoulders and sidewalls of the word line stacks 111 from damage during the first etching process, to maintain the shape of the word line stacks 111, thereby avoiding word line leakage issues. Here, the so-called high etching selectivity means that in the second etching step, a large amount of the dielectric layer 102 can be removed without removing or a small amount of the protective material 140 is removed. Therefore, the spacer 126 and the second capping layer 124 covered by the protective material 140 are not removed during the second etching step to maintain the shape of the word line stacks 111.

Here, after performing the first etching process, the dielectric layer 102 is patterned into the tunneling dielectric layer 112, and the protective material 140 is patterned into the protective layer 144, as shown in FIG. 1D. The protective layer 144 may be disposed on the tunneling dielectric layer 112 and cover the sidewall of the spacer 126. It should be noted that, in the present embodiment, the tunneling dielectric layer 112 has a protrusion 112p, and the protrusion 112p may protrude outward from the sidewall of the spacer 126 to the second opening 142. That is, a lateral width W1 of the tunneling dielectric layer 112 may be greater than a lateral width W2 of a pair of spacers 126. The first opening 141 is spatially connected with the corresponding second opening 142 to form a combined opening 145. In addition, after performing the first etching process, a bottom width of the first opening 141 is the same as an average width of the corresponding second opening 142.

Referring to FIG. 1D and FIG. 1E, a metal silicide layer 146 is formed at a bottom of the combined opening 145 to contact the substrate 100. A material of the metal silicide layer 146 includes cobalt silicide (CoSi), and may be formed by a metal silicidation process. Next, a plurality of contacts 150 are formed in the combined openings 145 (including the first openings 141 and the second openings 142), so as to accomplish the semiconductor device 1. Specifically, after forming the metal silicide layer 146, a liner layer 152 is formed to cover the protective layer 144, the protrusion 112p of the tunneling dielectric layer 112, and the metal silicide layer 146. Next, a metal material 154 is formed on the liner layer 152 to fill into the combined openings 145, thereby accomplishing the contacts 150.

A material of the liner layer 152 includes a barrier metal (e.g., Ti, TiN, Ta, TaN, or the

like), and may be formed by chemical vapor deposition. Different from the above-mentioned RF deposition process, the liner layer 152 formed by this chemical vapor deposition has better step coverage. That is, the liner layer 152 can be regarded as a conformal layer with a uniform thickness. The step coverage of the liner layer 152 is between 95% and 99%. The metal material 154 may include W, Cu, AlCu, or the like, and may be formed by physical vapor deposition. In addition, after depositing the metal material 154, a planarization process (e.g., CMP process) may be performed to remove the excess metal material 154 above the planarization layer 132 to avoid the short circuit issue of the contacts 150 between adjacent word line stacks 111. In this case, a top surface of the contact 150 may be substantially coplanar with the top surface of the planarization layer 132.

It should be noted that the liner layer 152 and the protective layer 144 may have the same material, such as TiN. The liner layer 152 and the protective layer 144 can be regarded as a combined liner layer 155 having the same material film. In addition, the protective layer 144 only covers the sidewall of the spacer 126 but does not cover the bottom surfaces of the combined openings 145, and the liner layer 152 conformally covers the protective layer 144 and the combined openings 145. Therefore, a thickness T3 of the combined liner layer 155 covering the sidewall of the spacer 126 may be greater than a thickness T4 of the combined liner layer 155 covering the metal silicide layer 146. A ratio of the thickness T3 to the thickness T4 may range from 1.2 to 1.5.

The present embodiment provides the semiconductor device 1 including: the substrate 100, the plurality of first gate structures 110, the spacer 126, and the plurality of contacts 150. Each first gate structure 110 may include: the tunneling dielectric layer 112 and the word line stacks 111 disposed on the tunneling dielectric layer 112. The spacer 126 may be disposed on the tunneling dielectric layer 112 and cover the sidewalls of the word line stacks 126 The plurality of contacts 150 may be respectively disposed between the plurality of first gate structures 110.

The tunneling dielectric layer 112 includes the protrusion 112 p protruding outward from the sidewall of the spacer 126 to the corresponding contact 150. Each contact 150 may include the combined liner layer 155 and the metal material 154. The combined liner layer 155 may cover the sidewall of the spacer 126, the protrusion 112 p of the tunneling dielectric layer 112, and the top surface of the substrate 100. The metal material 154 is disposed on the combined liner layer 155 so that the combined liner layer 155 surrounds the metal material 154. The semiconductor device 1 further includes the metal silicide layer 146 vertically disposed between the top surface of the substrate 100 and the combined liner layer 155. The contacts 150 may be source/drain contacts to be electrically connected to the source/drain regions (not shown) in the substrate 100 through the metal silicide layer 146.

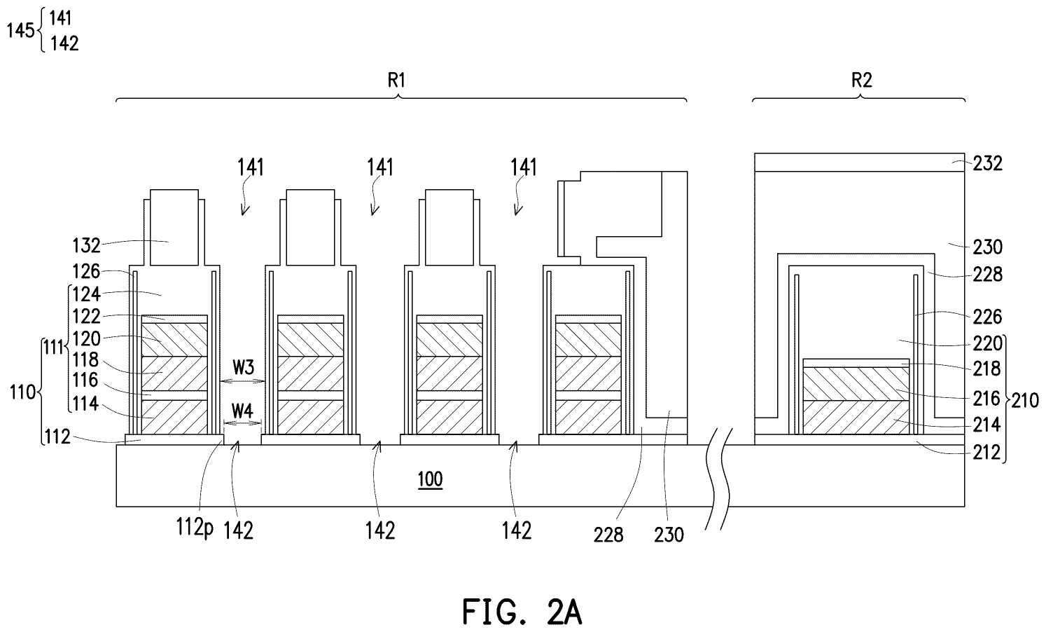

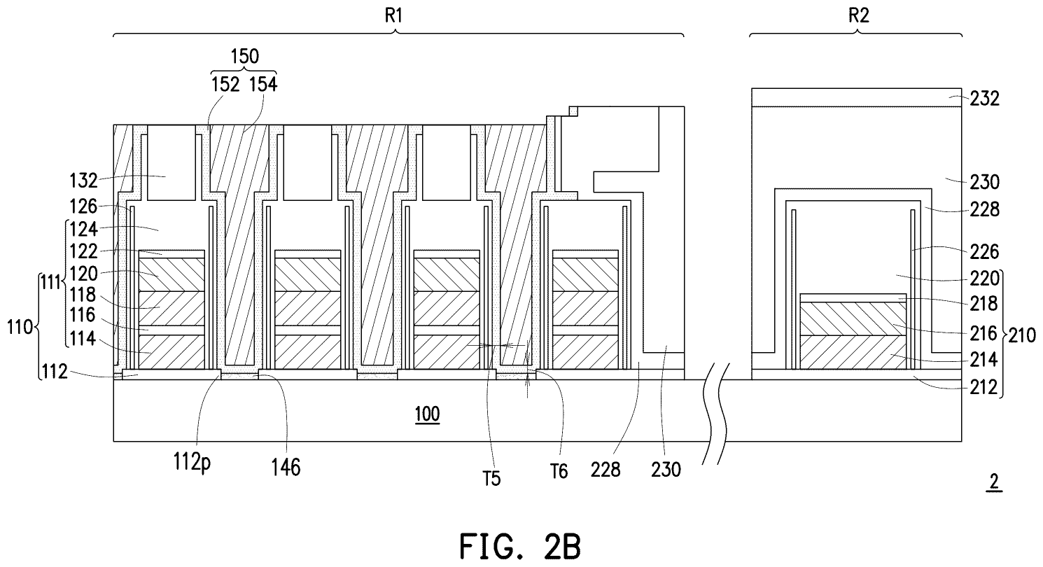

FIG. 2A to FIG. 2B are schematic cross-sectional views of a manufacturing process of a semiconductor device according to a second embodiment of the disclosure.

The manufacturing steps of FIG. 2A to FIG. 2B are performed with the structure of FIG.

1D. Referring to FIG. 1D and FIG. 2A, a second etching process is performed to completely remove the protective layer 144, thereby exposing the sidewall of the spacer 126. The second etching process may be a wet etching process, which has high etching selectivity with respect to the protective layer 144. Therefore, during the second etching process, the protective layer 144 may be completely removed without removing the spacer 126 or a small amount of the spacer 126 is removed. Since the protrusion 112p of the tunneling dielectric layer 112 protrudes outward from the sidewall of the spacer 126 to the second opening 142, a width W3 of the first opening 141 may be greater than a width W4 of the second opening 142 after the protective layer 144 is completely removed.

Referring to FIG. 2A and FIG. 2B, a metal silicide layer 146 is formed at the bottoms of the combined openings 145 to contact the substrate 100. It should be noted that the first opening 141 has the larger width W3 due to the absence of the protective layer 144, thus the metal silicide layer 146 can completely contact the top surface of the substrate 100. In this case, the metal silicide layer 146 may have a larger contact area to reduce the contact resistance between the source/drain region (not shown) in the substrate 100 and the subsequently formed contact 150. Next, a plurality of contacts 150 are formed in the combined openings 145 to accomplish a semiconductor device 2. Specifically, after forming the metal silicide layer 146, the liner layer 152 is formed to cover the spacer 126, the protrusion 112p of the tunneling dielectric layer 112, and the metal silicide layer 146. Next, a metal material 154 is formed on the liner layer 152 to fill into the combined openings 145, thereby accomplishing the contacts 150.

The material of the liner 152 includes a barrier metal (e.g., Ti, TiN, Ta, TaN, or the like), and may be formed by chemical vapor deposition. Different from the above-mentioned RF deposition process, the liner layer 152 formed by this chemical vapor deposition has better step coverage. That is, the liner layer 152 can be regarded as a conformal layer with a uniform thickness. Therefore, a thickness T5 of the liner layer 152 covering the sidewall of the spacer 126 may be substantially equal to a thickness T6 of the liner layer 152 covering the metal silicide layer 146. The metal material 154 may include W, Cu, AlCu, or the like, and may be formed physical vapor deposition.

In summary, in the embodiment of the present invention, after removing the sacrificial material between the plurality of word line stacks, a protective layer is formed to cover the surface of the plurality of word line stacks to prevent the subsequent etching process from damaging the shoulders and sidewalls of the plurality of word line stacks. In this case, the embodiment of the present invention can effectively solve the conventional word line leakage issue, thereby improving the yield and reliability of the semiconductor device.

What is claimed is:

1. A semiconductor device, comprising:
a plurality of gate structures disposed on a substrate, wherein each gate structure comprises:
a tunneling dielectric layer; and
a word line stack disposed on the tunneling dielectric layer;
a spacer disposed on the tunneling dielectric layer and covering a sidewall of the word line stack; and
a plurality of contacts respectively disposed between the plurality of gate structures, wherein the tunneling dielectric layer comprises a protrusion protruding outward from a sidewall of the spacer to a corresponding contact.

2. The semiconductor device according to claim 1, wherein each contact comprises:
a liner layer covering the sidewall of the spacer, the protrusion of the tunneling dielectric layer, and a top surface of the substrate; and
a metal material disposed on the liner layer.

3. The semiconductor device according to claim 2, wherein a first thickness of the liner layer covering the sidewall of the spacer is greater than a second thickness of the liner layer covering the top surface of the substrate.

4. The semiconductor device according to claim 3, wherein a ratio of the first thickness to the second thickness is between 1.2 and 1.5.

5. The semiconductor device according to claim 2, wherein a first thickness of the liner layer covering the sidewall of the spacer is substantially equal to a second thickness of the liner layer covering the top surface of the substrate.

6. The semiconductor device according to claim 2, further comprising: a metal silicide vertically disposed between the top surface of the substrate and the liner layer.

7. The semiconductor device according to claim 2, wherein the liner layer comprises TiN, and the metal material comprises W.

8. A method of forming a semiconductor device, comprising:
forming a dielectric layer on a substrate;
forming a plurality of word line stacks on the dielectric layer and a spacer covering a sidewall of the plurality of word line stacks;
forming a sacrificial material between the plurality of word line stacks;
removing the sacrificial material to form a plurality of first openings, wherein the plurality of first openings expose a surface of the dielectric layer;
forming a protective layer to cover a sidewall of the spacer and a bottom surface of the plurality of first openings;
with the protective layer in place, performing a first etching process to remove the protective layer and the dielectric layer at a bottom of the plurality of first openings, thereby forming a plurality of second openings in the dielectric layer to expose a bottom surface of the substrate; and
respectively forming a plurality of contacts in the plurality of first openings and the plurality of second openings.

9. The method of forming the semiconductor device according to claim 8, wherein the forming the protective layer comprises: performing a radiofrequency magnetron sputtering (RF) deposition process.

10. The method of forming the semiconductor device according to claim 8, wherein after forming the protective layer, a thickness of the protective layer covering the sidewall of the spacer is less than a thickness of the protective layer covering the bottom surface of the plurality of first openings.

11. The method of forming the semiconductor device according to claim 8, wherein after performing the first etching process, the method further comprises: performing a second etching process to completely removing the protective layer, thereby exposing the sidewall of the spacer.

12. The method of forming the semiconductor device according to claim 11, wherein after performing the second etching process, the plurality of first openings has a width greater than a width of the plurality of second openings.

13. The method of forming the semiconductor device according to claim 8, wherein after performing the first etching process, a plurality of tunneling dielectric layers are formed between the plurality of word line stacks and the substrate, and each tunneling dielectric layer comprises a protrusion protruding outward from the sidewall of the spacer to a corresponding contact.

14. The method of forming the semiconductor device according to claim 13, wherein each contact comprises:
a liner layer covering the sidewall of the spacer, the protrusion of the tunneling dielectric layer, and a top surface of the substrate; and
a metal material disposed on the liner layer.

15. The method of forming the semiconductor device according to claim 14, wherein the liner layer and the protective layer have the same material.

16. The method of forming the semiconductor device according to claim 14, wherein before forming the plurality of contacts, the method further comprises: forming a metal silicide layer on the top surface of the substrate, so that the metal silicide layer is vertically disposed between the top surface of the substrate and the plurality of contacts.

17. The method of forming the semiconductor device according to claim 8, wherein each first opening is spatially connected with a corresponding second opening.
